(19) United States
(12) Patent Application Publication
(10) Pub. No.: US 2011/0114914 A1
(43) Pub. Date: May 19, 2011

(54) FIELD EFFECT TRANSISTOR AND CIRCUIT DEVICE

(76) Inventors: Hideaki Numata, Tokyo (JP); Satoru Toguchi, Tokyo (JP); Hiroyuki Endoh, Tokyo (JP)

(21) Appl. No.: 13/055,807

(22) PCT Filed: Jun. 19, 2009
(86) PCT No.: PCT/JP2009/061173

§ 371 Date: Jan. 25, 2011

(30) Foreign Application Priority Data
Jul. 25, 2008 (JP) 2008-192642

(51) Int. Cl. H01L 29/12; B82Y 99/00

(52) U.S. Cl. 257/9; 257/E29.068; 977/811; 977/742

(57) ABSTRACT

An end portion (104a) of a first source electrode (104) and an end portion (105a) of a first drain electrode (105) face each other on a gate insulating film (103) via a channel formation region. The first source electrode (104) and first drain electrode (105) extend over steps, and the end portion (104a) and end portion (105a) face each other on the gate insulating film (103). The highest portions of the end portion (104a) and end portion (105a) are formed higher than the upper surface of the gate insulating film (103) serving as the channel formation region. A field-effect transistor of this invention also includes a second source electrode (107) which is formed in contact with the channel layer (106) and connects the first source electrode (104) and channel layer (106), and a second drain electrode (108) which is formed in contact with the channel layer (106) and connects, the first drain electrode (105) and channel layer (106).

### TECHNICAL FIELD

The present invention relates to a field-effect transistor which can be used as a thin-film transistor and can be manufactured by a printing method or the like, and a circuit device using the field-effect transistor.

### BACKGROUND ART

Thin-film transistors (TFTs) are widely used as pixel switching elements for display devices such as a liquid crystal display and EL display. Recently, it is growing popular to form even the driver circuit of a pixel array from TFTs on the same substrate. The TFTs are generally fabricated on a glass substrate using amorphous silicon or polysilicon. However, a CVD apparatus used to fabricate TFTs using silicon is very expensive. Larger-area display devices and the like using TFTs greatly raise the manufacturing cost.

The process of forming a film of amorphous silicon or polysilicon is performed at very high temperatures. Materials available as a substrate are, therefore, limited, and a lightweight resin substrate and the like cannot be adopted. To solve these problems, there have been proposed TFTs using organic materials or nanostructures such as carbon nanotubes and oxide nanowires, instead of amorphous silicon and polysilicon.

Carbon nanotubes (CNTs) are cylindrical carbon molecules, and are configured by rolling a graphene sheet consisting of six-membered rings of carbon atoms. A CNT obtained by rolling one graphene sheet into a cylindrical shape is called a single-walled nanotube (SWNT). A CNT having a multilayered structure of cylindrical carbon nanotubes different in diameter is called a multi-walled nanotube (MWNT). The SWNT has a diameter of about 1 nm, and the MWNT has a diameter of about several ten nm.

CTNs include various kinds of carbon nanotubes which differ in helicity (chirality) depending on the difference in the direction in which the graphene sheet is rolled, i.e., the difference in the orientation of six-member rings of carbon atoms with respect to the circumferential direction, in addition to the difference in diameter. Examples are a chiral carbon nanotube, zigzag carbon nanotube, and armchair carbon nanotube. The SWNT exhibits both metal and semiconductor properties in accordance with the difference in helicity (chirality).

A field-effect transistor (TFT) with a channel layer made of SWNTs can be fabricated by growing SWNTs having the above characteristics at random between source and drain electrodes by, e.g., chemical vapor deposition (CVD). The SWNT channel layer can be formed by dispersing CNTs in a liquid, and applying, depositing, or printing the dispersion on a substrate. Reference 1 (E. S. Snow et al., Applied Physics Letters, vol. 82, p. 2145, (2003)) reports that many contacts are formed in the thus-fabricated CNT random network to generate connections between carbon nanotubes, and these connections can be used for the channel layer of a thin-film transistor. In non-patent reference 1, when the single-walled carbon nanotube density in the channel layer was about 1 nanotube/μm², a five-digit on/off ratio and a mobility of 7 cm²/Vs were obtained, implementing a high-quality thin-film transistor (TFT).

As described above, the CNT random network can be formed by applying or printing a CNT dispersion. This process can increase the area at low cost, the process temperature is low, and there are few limitations on selection of a material used as a substrate. This CNT random network can greatly suppress the manufacturing cost, compared to a silicon-based TFT formed on a glass substrate that is adopted in the related technology. In recent years, TFTs using CNT random networks have been reported actively. Examples of the report are reference 2 (E. Artukovic, M. Kaempgen, D. S. Hecht, S. Roth, G. Gruner, Nano Letters vol. 5, p. 757, (2005)), reference 3 (S.-H. Hur, O. O. Park, J. A. Rogers, Applied Physics Letters, vol. 86, p. 243502, (2005)), and reference 4 (T. Takenobu, T. Takahashi, T. Kanbara, K. Tsukagoshi, Y. Aoyagi, Y. Iwasa, Applied Physics Letters, vol. 88, p. 33511, (2006)).

Recently, TFTs in which the channel is formed using a plurality of semiconductive zinc oxide nanowires excellent in crystallinity have been reported in reference 5 (Duk-II Suh, Seung-Yong Lee, Jung-Hwan Hyung, Tae-Hong Kim, Sang-Kwon Lee, J. Phys. Chem. C, vol. 112, pp. 1276 -1281, (2008)), and the like. The techniques described in non-patent references 2 to 5 focus on channel layers made of materials having nanostructures, and have yielded some results regarding channel formation exploiting a solution process and the like. However, formation of an electrode to form an electric contact in a channel layer made of nanostructures uses well-known vacuum film formation, photolithography, and the like.

### DISCLOSURE OF INVENTION

### Problems To Be Solved By the Invention

To manufacture large-area semiconductor devices such as a large-screen flat-panel display at low cost, not only a semiconductor material for forming a channel, but also all elements which form a semiconductor device, including an interconnection, electrode, and insulator, are desirably formed by a printing method. As is well known, the manufacture by the printing method can reduce the manufacturing cost. By using the printing method, a pattern is formed at only a necessary portion with a minimum material, greatly reducing materials and energy applied in the manufacture, compared to the manufacture of a semiconductor by CVD using silicon. Also, wastes produced in the manufacture can also be greatly decreased, reducing the environment load. However, several problems arise when all the building elements of a semiconductor device are formed by the printing method.

In general, to improve the electrical characteristics of a MOS field-effect transistor, it is necessary to, for example, improve the electrical characteristics of the channel layer, improve the characteristics of the gate insulating film, and reduce the contact resistance at the interface between the channel layer and the source and drain electrodes. Especially, to improve the characteristics of a TFT having a channel layer composed of a plurality of nanomaterials such as CNTs, it is important to reduce the electrical resistance at the interface between the channel layer and the source and drain electrodes.

However, a TFT using a CNT random network for the channel layer cannot obtain an expected ON current and ON/OFF′ ratio because of the following factors.

First, the nanomaterial such as the CNT is small in contact area with an electrode metal owing to its smallness.

Second, a Schottky barrier is generated at the interface owing to an electronic state mismatch between the semiconductor layer (channel layer) and the electrode metal.

The contact resistance between the channel layer and the electrode can be reduced using a material having a work function of a magnitude compliant with the conductive characteristic of the channel layer. However, such a material is generally expensive and raises the cost when many TFTs are used to, for example, form a large-screen flat-panel display.

In the manufacture of a semiconductor device by a printing method such as screen printing or an inkjet method, it is desirable to draw each device element at a minimum amount of ink (material). In a manufacturing process using many planarization steps, as employed in the manufacture of a general silicon semiconductor, the amount of material used increases, the number of manufacturing steps such as the through-hole formation step increases, and the cost rises.

However, when manufacturing a device (e.g., TFT) having a multilayered structure without using the planarization step, a step generated by each building element of the device needs to be carefully considered. Particularly, the manufacture of a semiconductor device by a printing method uses a fluid liquid material, and the liquid material may run off the step, increasing the risk of a disconnection or deformation of a printed/drawn pattern. In this state, no accurate arrangement relationship (contact state) can be obtained between the channel layer made of the nanomaterial, and the electrode. Neither an expected ON current nor ON/OFF ratio can be achieved.

The present invention has been made to solve the above problems of the silicon-based technique, and has as its exemplary object to obtain an expected ON current and ON/OFF ratio while suppressing the rise of the cost.

### Means of Solution To the Problems

A field-effect transistor according to the present invention comprises at least a gate electrode which is formed. on a substrate, a gate insulating film which is formed to cover a channel formation region of an upper surface of the gate electrode, and cover part of a first side portion and part of a second side portion of the gate electrode that face each other, a first electrode and a second electrode which are formed on side of the first side portion and on side of the second side portion, respectively, the first electrode and the second electrode having end portions facing each other on the gate insulating film via the channel formation region, a channel layer which is formed in the channel formation region on the gate insulating film, a third electrode which is formed in contact with the channel layer on the side of the first side portion, and connects the first electrode and the channel layer, and a fourth electrode which is formed in contact with the channel layer on the side of the second side portion, and connects the second electrode and the channel layer, wherein highest portions of the facing end portions of the first electrode and the second electrode are formed higher than an upper surface of the gate insulating film in the channel formation region.

### Effects of the Invention

As described above, according to the present invention, the first and second electrodes are arranged so that their end portions face each other on a gate insulating film via a channel formation region. In addition, the highest portions of the facing end portions of the first and second electrodes are formed higher than the upper surface of the gate insulating film in the channel formation region. The third electrode connects the first electrode and a channel layer. The fourth electrode connects the second electrode and the channel layer. While suppressing the rise of the cost, an expected ON current and ON/OFF ratio can be obtained.

### BRIEF DESCRIPTION OF DRAWINGS

FIG. 1 is a sectional view schematically showing an example of the structure of a field-effect transistor in the first exemplary embodiment of the present invention;

FIG. 2 is a plan view schematically showing an example of the structure of the field-effect transistor in the first exemplary embodiment of the present invention;

FIG. 3 is a sectional view schematically showing an example of the structure of a field-effect transistor in the second exemplary embodiment of the present invention;

FIG. 4 is a plan view schematically showing an example of the structure of the field-effect transistor in the second exemplary embodiment of the present invention;

FIG. 5 is a sectional view schematically showing an example of the structure of a field-effect transistor in the third exemplary embodiment of the present invention;

FIG. 6 is a sectional view schematically showing an example of the structure of a field-effect transistor in the fourth exemplary embodiment of the present invention;

FIG. 7 is a sectional view schematically showing an example of the structure of a field-effect transistor in the fifth exemplary embodiment of the present invention;

FIG. 8 is a sectional view schematically showing an example of the structure of a field-effect transistor in the sixth exemplary embodiment of the present invention;

FIG. 9 is a plan view showing an example of the arrangement of part of a circuit device in the seventh exemplary embodiment of the present invention;

FIG. 10 is a circuit diagram showing an example of the structure of the basic cell of the circuit device in the exemplary embodiment of the present invention;

FIG. 11 is a circuit diagram showing another example of the structure of the basic cell; and

FIG. 12 is a circuit diagram showing still another example of the structure of the basic cell.

### BEST MODE FOR CARRYING OUT THE INVENTION

Exemplary embodiments of the present invention will be described below with reference to the accompanying drawings.

### First Exemplary Embodiment

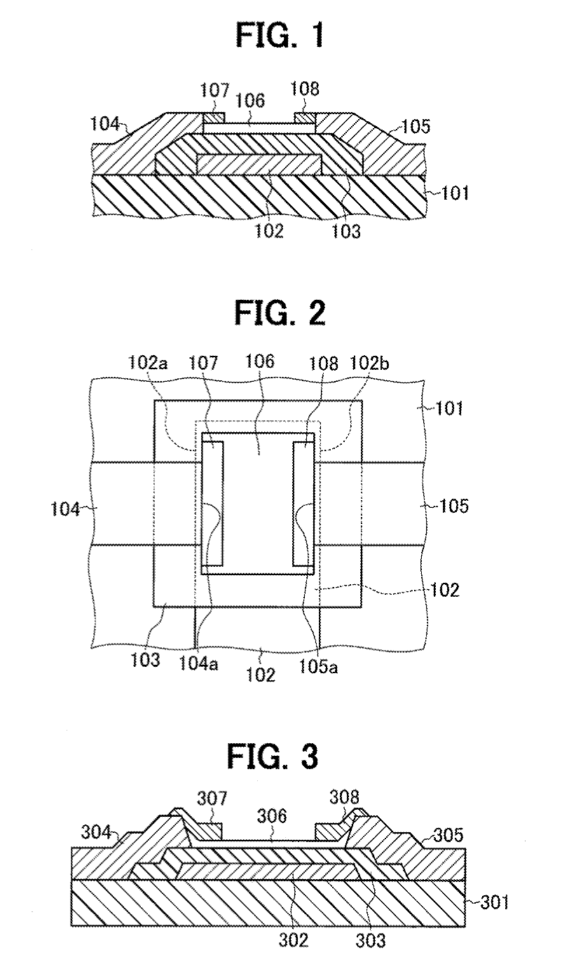

The first exemplary embodiment of the present invention will be described with reference to FIGS. 1 and 2. FIG. 1 is a sectional view schematically showing an example of the structure of a field-effect transistor in the first exemplary embodiment. FIG. 2 is a plan view schematically showing an example of the structure of the field-effect transistor in the first exemplary embodiment. This transistor includes a substrate 101, a gate electrode 102 formed on the substrate 101, and a gate insulating film 103 which is formed to cover the channel formation region of the upper surface of the gate electrode 102, and cover part of a first side portion 102a and part of a second side portion 102b of the gate electrode 102 that face each other. The gate electrode 102 is insulated on the substrate 101. The gate electrode 102 can be insulated by, for example, forming the substrate 101 from an insulating material.

The transistor also includes a first source electrode (first electrode) 104 formed on the side of the first side portion 1026, and a first drain electrode (second electrode) 105 formed on the side of the second side portion 102b, between which the channel formation region is interposed. An end portion 104a of the first source electrode 104 and an end portion 105a of the first drain electrode 105 face each other on the gate insulating film 103 via the channel formation region. In general, the gate insulating film 103 formed with a thickness has steps at these end portions. The first source electrode 104 and first drain electrode 105 extend over these steps, and the end portions 104a and 105a face each other on the gate insulating film 103. The highest portions of the end portions 104a and 105a of the first source electrode 104 and first drain electrode 105 which extend over the upper steps of the gate insulating film 103 are formed higher than the upper surface of the gate insulating film 103 that serves as the channel formation region.

The field-effect transistor in the first exemplary embodiment also includes a channel layer 106 which is formed in the channel formation region on the gate insulating film 103, a second source electrode (third electrode) 107 which is formed in contact with the channel layer 106 on the side of the first side portion 102a and connects the first source electrode 104 and channel layer 106, and a second drain electrode (fourth electrode) 108 which is formed in contact with the channel layer 106 on the side of the second side portion 102b and connects the first drain electrode 105 and channel layer 106. The second source electrode 107 and second drain electrode 108 ohmic-contact the channel layer 106.

A method of manufacturing the field-effect transistor in the first exemplary embodiment will be explained. First, a pattern is formed from a conductive paste (ink) on a substrate 101 and baked, forming a gate electrode 102. Pattern formation suffices to use a well-known printing method such as a screen printing method or inkjet method.

Then, an insulating material made of, e.g., a synthetic resin is applied and thermally cured, forming a gate insulating film 103.

Patterns are formed from a conductive paste and baked, forming a first source electrode 104 and first drain electrode 105. Pattern formation suffices to use a well-known screen printing method or inkjet method.

A channel layer 106 is formed in a region (channel formation region) interposed between the first source electrode 104 and the first drain electrode 105 on the gate insulating film 103. For example, the channel layer 106 is formed from a plurality of carbon nanotubes having p-type semiconductor characteristics. It suffices to form the carbon nanotubes by, e.g., an inkjet method using carbon nanotube-dispersed ink.

A second source electrode 107 and second drain electrode 108 are formed to contact the channel layer 106. The second source electrode 107 and second drain electrode 108 are formed by forming patterns by, e.g., an inkjet method using an ink mainly containing palladium which has a large work function and can ohmic-contact a CNT random network that forms the channel layer 106, and by baking the patterns.

The second source electrode 107 and second drain electrode 108 are formed to connect the channel layer 106 to the first source electrode 104 and first drain electrode 105. According to the first exemplary embodiment, the end portion 104a of the first source electrode 104 and the end portion 105a of the first drain electrode 105 face each other on the gate insulating film 103 via the channel formation region. Thus, the interval between the first source electrode 104 and the channel layer 106 and that between the first drain electrode 105 and the channel layer 106 are narrow. For example, in the exemplary embodiment exemplified in FIG. 1, the first source electrode 104 and first drain electrode 105 contact the channel layer 106. According to the first exemplary embodiment, it suffices to form the second source electrode 107 and second drain electrode 108 in dimensions of about several nm in the longitudinal direction of the gate. The second source electrode 107 and second drain electrode 108 can be formed from a very small pattern.

As described above, an expensive material such as palladium is used when the channel layer 106 formed from carbon nanotubes is used, and source and drain electrodes are formed to suppress formation of a barrier such as a Schottky barrier and ohmic-contact the channel layer 106. However, according to the first exemplary embodiment, the second source electrode 107 and second drain electrode 108 are formed from a small pattern, as described above, so the amount of expensive material used is small, suppressing the rise of the cost.

The Schottky barrier between the channel layer and the electrode will be explained. As is well known, the Schottky barrier arises from a depletion layer which is generated at the interface of a semiconductor when carriers near the interface in the semiconductor move to a metal owing to the difference in work function or ionization energy between the metal and the semiconductor. To decrease the contact resistance at the interface between the semiconductor and the metal caused by the Schottky barrier, it is necessary to make the work functions (ionization potentials) of two materials in contact with each other as equal as possible, and decrease the height of the energy barrier of the generated Schottky barrier.

For example, to make a contact with a p-type semiconductor, gold, platinum, iridium, palladium; cobalt, nickel, and the like having large work functions are suitable. To the contrary, to make a contact with an n-type semiconductor, silver, aluminum, titanium, tantalum, niobium, zinc, tin, indium, gallium, manganese, and the like having small work functions are suited. Of these materials, gold, platinum, iridium, palladium, and indium are relatively expensive materials, and the amounts of them used need to be decreased to reduce the manufacturing cost.

The manufacture of a field-effect transistor by a printing method uses a fluid liquid material. In the manufacture of a device having a multilayered structure, the liquid material may run off a step generated by each device element, increasing the possibility at which wiring and electrode contact failures occur. To prevent these failures and ensure the reliability of the field-effect transistor, the liquid material needs to be used by an amount enough to cover the step.

In contrast, the first source electrode 104 and first drain electrode 105 suffice to obtain electrical connections with the second source electrode 107 and second drain electrode 108, and need not use an expensive metal material. Even if the first source electrode 104 and first drain electrode 105 are formed from a large pattern, the cost does not rise.

As is apparent from the above description, in the field-effect transistor according to the first exemplary embodiment, the interval between the second source electrode 107 and the second drain electrode 108 determines the channel length. The widths of those portions of the second source electrode 107 and second drain electrode 108, that face each other, determine the channel width. As is well known, the characteristics of the field-effect transistor greatly depend on the channel length and channel width. In the field-effect transistor according to the first exemplary embodiment, the second source electrode 107 and second drain electrode 108 can be formed by an inkjet method or the like, as described above, are formed from a small pattern using a small amount of material ink, and thus are excellent in dimensional accuracy in pattern formation.

The highest portions of the end portions 104a and 105a of the first source electrode 104 and first drain electrode 105 which extend over the upper steps of the gate insulating film 103 are formed higher than the upper surface of the gate insulating film 103. Even when the pattern is formed from a paste (paste) material, as described above, the spread of the paste (ink) patterns serving as the second source electrode 107 and second drain electrode 108 to the periphery of the gate insulating film 103 can be suppressed, facilitating control of the pattern shape.

In the above-described fabrication process, the process temperature is low, and most engineering plastics (resins) and a stack (resin laminated film) of these resin films are available as the material of the substrate 101. This can add a value to a manufactured semiconductor device, including flexibility and transparency which cannot be implemented in a solid silicon semiconductor integrated circuit. Further, no expensive vacuum apparatus is used, and the manufacturing cost can be suppressed low.

### Second Exemplary Embodiment

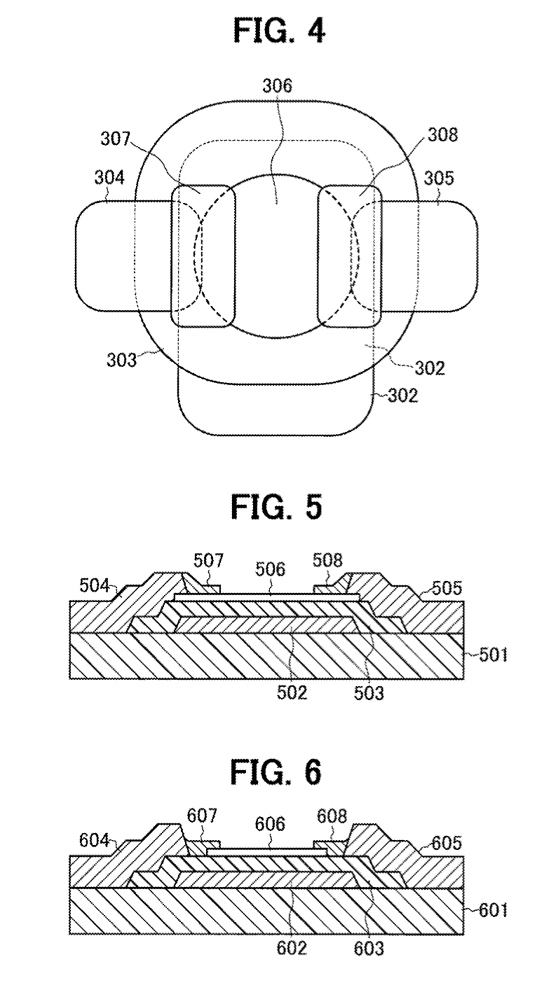

The second exemplary embodiment of the present invention will be described with reference to FIGS. 3 and 4. FIG. 3 is a sectional view schematically showing an example of the structure of a field-effect transistor in the second exemplary embodiment. FIG. 4 is a plan view schematically showing an example of the structure of the field-effect transistor in the second exemplary embodiment. This transistor includes a substrate 301 made of a resin, a gate electrode 302 formed on the substrate 301, and a gate insulating film 303 which is formed to cover the channel formation region of the upper surface of the gate electrode 302, and cover part of the first side portion and that of the second side portion of the gate electrode 302 that face each other. As shown in FIG. 4, the gate insulating film 303 is formed to cover the upper surface and three side portions of the gate electrode 302.

The transistor also includes a first source electrode 304 and first drain electrode 305 which are formed so that their end portions face each other on the gate insulating film 303 via the channel formation region. In general, the gate insulating film 303 formed with a thickness has steps at these end portions. The first source electrode 304 and first drain electrode 305 extend over these steps, and their end portions face each other on the gate insulating film 303. Since the gate insulating film 303 is formed on the gate electrode 302 having a thickness, steps are formed on the gate insulating film 303 even at end portions corresponding to the end portions of the gate electrode 302. In the second exemplary embodiment, the first source electrode 304 and first drain electrode 305 extend over even the steps generated by the gate electrode 302.

The highest portions of the facing end portions of the first source electrode 304 and first drain electrode 305 which extend over the upper steps of the gate insulating film 303 are formed higher than the upper surface of the gate insulating film 303 that serves as the channel formation region.

The channel formation region on the gate insulating film 303 includes a channel layer 306 formed from, e.g., a random network of carbon nanotubes (CNTs), a second source electrode 307 which is formed in contact with the channel layer 306 on the side of the first side portion and connects the first source electrode 304 and channel layer 306, and a second drain electrode 308 which is formed in contact with the channel layer 306 on the side of the second side portion and connects the first drain electrode 305 and channel layer 306. The second source electrode 307 and second drain electrode 308 ohmic-contact the channel layer 306.

A method of manufacturing the field-effect transistor in the second exemplary embodiment will be explained. First, a 75-μm thick polyimide substrate 301 is prepared. An ink of a dispersion in which silver nanoparticles are dispersed in a medium is prepared. This ink is applied to the prospective portion of the gate electrode 302 using, e.g., an inkjet printer, and dried, forming a gate electrode pattern on the substrate 301.

The gate electrode pattern is heated to 200° C. to be baked and sintered, forming a gate electrode 302 on the substrate 301.

A coating solution containing an insulating material of an organic polymer such as polyimide is applied by a dispenser to cover the upper surface and three side surfaces of the gate electrode 302, forming an insulating applied pattern. Then, the insulating applied pattern is heated to 180° C. to be cured, forming a gate insulating film 303 on the gate electrode 302. The thickness of the gate insulating film 303 is not particularly limited. However, if the gate insulating film 303 is excessively thin, it becomes difficult to effectively suppress the leakage current between the gate electrode 302 and another electrode. In contrast, if the gate insulating film 303 is excessively thick, the switching phenomenon of the channel layer 306 by the gate bias voltage cannot be effectively controlled. From this, the thickness of the gate insulating film 303 preferably falls within the range of 10 to 1,000 nm.

After that, a first source electrode 304 and first drain electrode 305 are formed. First, an electrode paste is prepared by mixing, with a binder resin, silver nanoparticles whose surface is stabilized by an organic material. For example, an electrode paste is prepared, in which silver nanoparticles having a surface covered with molecules of an organic material such as alkylamine and having an average grain diameter of about 20 nm are dispersed in a binder resin containing a substance which reacts with the surface-covering molecules upon heating.

By using, e.g., a well-known screen printing method, paste patterns each of which is made of the electrode paste and has a desired electrode shape are formed at predetermined positions on the gate insulating film 303 and substrate 301, and dried. Then, the formed paste patterns are heated to 180° C. and baked to sinter the silver nanoparticles, forming the first source electrode 304 and first drain electrode 305 at predetermined positions on the gate insulating film 303 and substrate 301.

Next, a channel layer 306 is formed in a region (channel formation region) interposed between the first source electrode 304 and the first drain electrode 305 on the gate insulating film 303. First, a CNT ink is prepared by dispersing, in dichloroethane (dispersion medium), single-walled nanotubes exhibiting semiconductor properties. Then, the CNT ink is dropped to a predetermined location using a dispenser, forming an ink pattern serving as the channel layer 306. The ink pattern is dried to evaporate the dispersion medium, forming the channel layer 306 from the CNT random network. The CNT random network is a p-type semiconductor.

Thereafter, a second source electrode 307 and second drain electrode 308 are formed to contact the channel layer 306. The second source electrode 307 and second drain electrode 308 use an ink mainly containing palladium which has a large work function and can ohmic-contact the CNT random network that forms the channel layer 306. A pattern to contact both the first source electrode 304 and channel layer 306, and a pattern to contact both the first drain electrode and channel layer 306 are formed from the ink using, e.g., an inkjet printer. The thus-formed ink patterns are heated to 180° C. to be baked and sintered, forming the second source electrode 307 and second drain electrode 308.

In the above-described fabrication process, the process temperature is low, and most engineering plastics are available as the material of the substrate 301. This can add a value to a manufactured semiconductor device, including flexibility and transparency which cannot be implemented in a solid silicon semiconductor integrated circuit. Also, no expensive vacuum apparatus is used, and the manufacturing cost can be suppressed low.

In the second exemplary embodiment, the patterns of the electrode and the like are formed using an inkjet printer, dispenser, screen printing, and the like. However, the formation is not limited to them, and even a means such as letterpress printing, intaglio printing, or offset printing is similarly usable.

The field-effect transistor in the second exemplary embodiment uses a CNT random network of a p-type semiconductor as the channel layer 306. To reduce a Schottky barrier which determines the contact resistance at the interface between the semiconductor and the metal, palladium having a large work function (about 5.1 eV) is used as the material of the second source electrode 307 and second drain electrode 308. This can decrease the ON resistance of the field-effect transistor and ensure a large driving current. Although palladium is an expensive metal, the amount used is small, as is apparent from the device structure in FIG. 1. Thus, the manufacturing cost hardly increases along with the improvement of device characteristics.

The first source electrode 304 and first drain electrode 305 extend over steps generated owing to the thicknesses of the gate electrode 302 and gate insulating film 303. The first source electrode 304 and first drain electrode 305 use silver which is lower in cost than palladium, and even if they are formed much thicker than the steps, the cost hardly rises. Forming a thick first source electrode 304 and first drain electrode 305 ensures reliability at the steps. Note that silver has a work function as small as about 4.3 eV, and is not suited as a material which directly contacts a p-type CNT random network.

The second exemplary embodiment adopts metal palladium as a material having a large work function, but can also use an organic conductive material. In general, organic materials are often larger in ionization potential than metal materials, and there are many choices as the hole injection material. Organic materials are suitable for even a printing method.

As is apparent from the plan view (FIG. 4) of the field-effect transistor according to the present invention, the second source electrode 307 and second drain electrode 308 define the channel length (L) and channel width (W) of the TFT. It is a known fact that the characteristics of the field-effect transistor greatly depend on the channel length (L) and channel width (W). In the field-effect transistor according to the second exemplary embodiment, the second source electrode 307 and second drain electrode 308 are formed using a very small amount of material ink, and thus are excellent in pattern accuracy in printing formation.

Especially when the channel layer 306 is a random network made of a nanomaterial such as a plurality of CNTs, the electrode material ink sometimes permeates into the channel layer 306 owing to capillarity. This effect improves the contact between the nanomaterial and the electrode material, but causes “bleeding” of the electrode pattern and varies device characteristics. In the field-effect transistor according to the present invention, the degree of “bleeding” can be controlled to minimize variations of electrode patterns by forming the second source electrode 307 and second drain electrode 308 using a small amount of material ink. As a consequence, a plurality of field-effect transistors with high uniformity can be manufactured. The operating margin of an integrated circuit which operates using a plurality of devices in the second exemplary embodiment becomes wide, increasing the manufacturing yield.

### Third Exemplary Embodiment

The third exemplary embodiment of the present invention will be described with reference to FIG. 5. FIG. 5 is a sectional view schematically showing an example of the structure of a field-effect transistor in the third exemplary embodiment. In the field-effect transistor according to the third exemplary embodiment, a gate electrode 502 is formed on a resin substrate 501, and a gate insulating film 503 is formed to cover the upper surface and 50 side surfaces of the gate electrode 502. Further, a channel layer 506 is formed on the gate insulating film 503.

A first source electrode 504 and first drain electrode 505 are formed on top of steps generated owing to the thicknesses of the gate electrode 502 and gate insulating film 503, and are in contact with the channel layer 506. A second source electrode 507 is formed in contact with both the first source electrode 504 and channel layer 506. A second drain electrode 508 is formed in contact with both the first drain electrode 505 and channel layer 506.

In the fabrication of the field-effect transistor according to the above-described second exemplary embodiment, the channel layer is formed after forming the first source electrode and first drain electrode. In the field-effect transistor according to the third exemplary embodiment, the first source electrode 504 and first drain electrode 505 are formed after forming the channel layer 506. The difference in the order of the manufacturing steps appears at the interface between the channel layer 506 and the first source electrode 504 and that between the channel layer 506 and the first drain electrode 505. In the second exemplary embodiment (FIG. 3), the channel layer 306 is formed using a liquid material after forming the first source electrode 304 and first drain electrode 305, so the two ends of the channel layer 306 swell owing to the wettability of the liquid material with the first source electrode 304 and first drain electrode 305.

To form the second source electrode 507 and second drain electrode 508 into more accurate shapes, the channel layer 506 is desirably flat. In the field-effect transistor according to the third exemplary embodiment, the channel layer 506 is formed at the flat portion of the gate insulating film 503, and thus can be formed flat without the influence of a step generated by the electrode or the like. The first source electrode 504 and first drain electrode 505 are formed preferably using a method capable of using a high-viscosity paste ink, such as a screen printing method, offset printing method, or dispenser. By using the high-viscosity ink material, no ink runs off a plurality of steps, and an electrode pattern can be formed at high dimensional accuracy. Permeation of the ink into the channel layer 506 by capillarity can also be suppressed.

The surface of the channel layer 506 serving as an undercoating for forming the second source electrode 507 and second drain electrode 508 is flatter than that of the channel layer 506 in the first exemplary embodiment. Hence, an electrode pattern can be printed and formed at higher accuracy. This enables manufacturing a plurality of field-effect transistors with high uniformity. When operating an integrated circuit using a plurality of field-effect transistors in the third exemplary embodiment, the operating margin can become wide, increasing the manufacturing yield.

### Fourth Exemplary Embodiment

The fourth exemplary embodiment of the present invention will be described with reference to FIG. 6. FIG. 6 is a sectional view schematically showing an example of the structure of a field-effect transistor in the fourth exemplary embodiment. In the field-effect transistor according to the fourth exemplary embodiment, a gate electrode 602 is formed on a substrate 601. A gate insulating film 603 is formed to cover the upper surface and three side surfaces of the gate electrode 602.

Similar to the above-described exemplary embodiments, a first source electrode 604 and first drain electrode 605 are formed on top of steps generated owing to the thicknesses of the gate electrode 602 and gate insulating film 603. A channel layer 606 is formed in a region interposed between the first source electrode 604 and the first drain electrode 605 on the gate insulating film 603.

In the fourth exemplary embodiment, the channel layer 606 contacts neither the first source electrode 604 nor first drain electrode 605, and has intervals (gaps) with the first source electrode 604 and first drain electrode 605. In the fourth exemplary embodiment, a second source electrode 607 is formed to fill the gap and contact both the first source electrode 604 and channel layer 606. Similarly, a second drain electrode 608 is formed to fill the gap and contact both the first drain electrode 605 and channel layer 606.

A method of manufacturing the field-effect transistor in the fourth exemplary embodiment will be exemplified. An ink pattern with a desired shape serving as the gate electrode 602 is drawn (formed) on a 100-μm thick polyethylene terephthalate substrate 601 by, e.g., a screen printing method using an ink in which silver nanoparticles are dispersed in a medium. This pattern is then dried. The formed pattern is heated to 160° C. to be baked and sintered, forming a gate electrode 602.

A solution of an insulating material containing an organic polymer such as polymethyl methacrylate (PMMA) is applied by a dispenser to cover the upper surface and three side surfaces of the gate electrode 602. The formed pattern is fired (thermally cured) at 170° C., forming a gate insulating film 603. The thickness of the gate insulating film 603 is not particularly limited. However, if the gate insulating film 603 is excessively thin, it becomes difficult to effectively suppress the leakage current between the gate electrode and another electrode. If the gate insulating film 603 is excessively thick, the switching phenomenon of an active layer by the gate bias voltage cannot be effectively controlled. Thus, the thickness of the gate insulating film 603 preferably falls within the range of 10 to 1,000 nm.

Thereafter, a first source electrode 604 and first drain electrode 605 are formed. First, a paste is prepared by mixing, with multi-walled nanotubes, silver nanoparticles whose surface is stabilized by an organic material. Then, the paste is formed into desired patterns each compliant with an electrode shape using, e.g., an offset printing method, and the formed patterns are dried. The formed patterns are heated to 150° C. to be baked and sintered, forming the first source electrode 604 and first drain electrode 605.

After forming the first source electrode 604 and first drain electrode 605 in the above way, an ink in which zinc oxide nanowires exhibiting semiconductor characteristics are dispersed in isopropyl alcohol is dropped to a. predetermined location (channel formation region) between the electrodes using a dispenser, and dried, forming a channel layer 606 from a random network of the zinc oxide nanowires. In the fourth exemplary embodiment, the channel layer 606 contacts neither the first source electrode 604 nor first drain electrode 605, and has gaps with the first source electrode 604 and first drain electrode 605. The zinc oxide nanowire is an n-type semiconductor.

If the electrode (metal material) contacts the channel layer 606 formed from ZnO nanowires which are a semiconductor, a Schottky barrier is formed, as described above. To decrease the Schottky barrier and obtain a good electrical contact, a material having a small work function is suitable. In the fourth exemplary embodiment, the second source electrode 607 and second drain electrode 608 are formed using an ink mainly containing, e.g., indium whose work function is as small as about 4.1 eV. The second source electrode 607 and second drain electrode 608 are formed by printing using an inkjet printer so that the second source electrode 607 contacts both the first source electrode 604 and channel layer 606, and the second drain electrode 608 contacts both the first drain electrode 605 and channel layer 606. The second source electrode 607 and second drain electrode 608 are sintered at 160° C.

As described above, in the fabrication process of forming electrodes and layers by forming a pattern using a resin-based paste or ink and baking it, the process temperature is low, and most engineering plastics are available as the material of the substrate 601. This can add a value to a manufactured semiconductor device, including flexibility and transparency which cannot be implemented in a solid silicon semiconductor integrated circuit. Further, no expensive vacuum apparatus is used, and the manufacturing cost can be suppressed low. Needless to say, the present invention is not limited to this example, and various printing methods are applicable.

In the field-effect transistor according to the fourth exemplary embodiment, indium having a small work function (about 4.1 eV) is used as the material of the second source electrode 607 and second drain electrode 608 to decrease the Schottky barrier with respect to the channel layer 606 of the n-type semiconductor. This can decrease the ON resistance of the field-effect transistor and ensure a large driving current. Although indium is an expensive metal, the amount used is small because the second source electrode 607 and second drain electrode 608 can be formed from a small pattern, in other words, no large pattern need be formed. Hence, the manufacturing cost hardly increases along with the improvement of device (transistor) characteristics.

The first source electrode 604 and first drain electrode 605 extend over steps generated owing to the thicknesses of the gate electrode 602 and gate insulating film 603. The first source electrode 604 and first drain electrode 605 use a material which is lower in cost than indium, and even if they are formed much thicker than the steps, the cost hardly rises. Forming a thick first source electrode 604 and first drain electrode 605 ensures reliability at the steps.

In the fourth exemplary embodiment, gaps are intentionally formed between the first source electrode 604 and first drain electrode 605, and the channel layer 606. These gaps function as ink reservoirs when printing and drawing a fine second source electrode 607 and second drain electrode 608, enhancing the pattern formation stability of the second source electrode 607 and second drain electrode 608.

Moreover, the second source electrode 607 and second drain electrode 608 are printed and drawn at flat exposed portions of the upper surface of the gate insulating film 603. The upper surface of the gate insulating film 603 can be modified by corona discharge, ultraviolet irradiation, or the like, improving the adhesive property. The patterns of the second source electrode 607 and second drain electrode 608 can be formed at higher accuracy.

With these effects, variations and failures of electrode patterns can be minimized, and a plurality of field-effect transistors with high uniformity can be manufactured. When operating an integrated circuit using a plurality of field-effect transistors in the fourth exemplary embodiment, the operating margin can become wide, increasing the manufacturing yield.

### Fifth Exemplary Embodiment

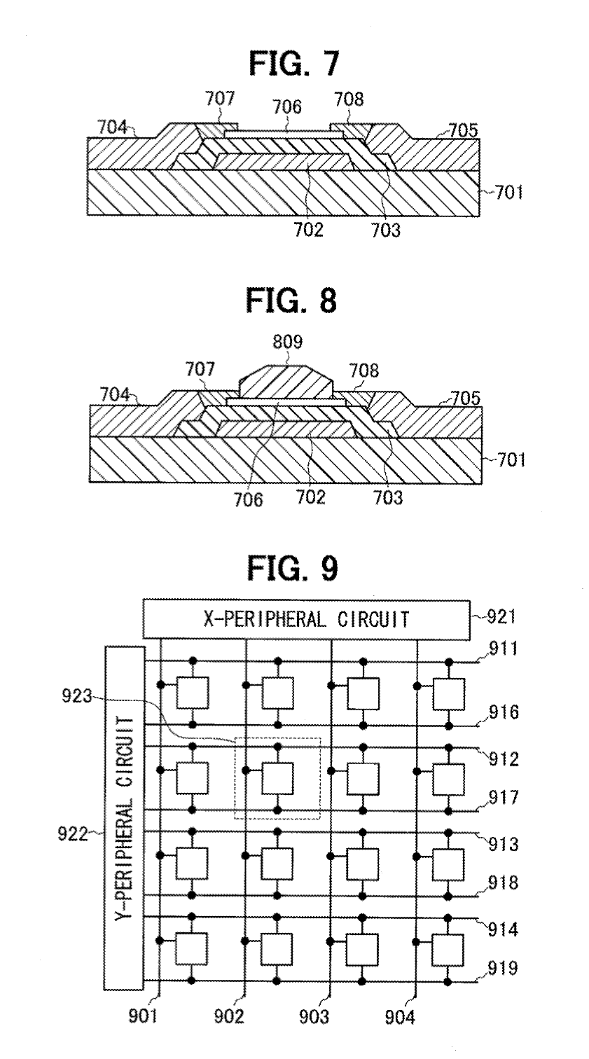

The fifth exemplary embodiment of the present invention will be described with reference to FIG. 7. FIG. 7 is a sectional view schematically showing an example of the structure of a field-effect transistor in the fifth exemplary embodiment. In the field-effect transistor according to the fifth exemplary embodiment, a gate electrode 702 is formed on a substrate 701 made of, e.g., an organic resin. A gate insulating film 703 is formed to cover the upper surface and three side surfaces of the gate electrode 702. A first source electrode 704 and first drain electrode 705 are formed so that they extend over steps generated owing to the thickness of the gate insulating film 703, and contact steps generated owing to the thickness of the gate electrode 702.

A channel layer 706 is formed in a region interposed between the first source electrode 704 and the first drain electrode 705 on the gate insulating film 703. Even in the fifth exemplary embodiment, similar to the fourth exemplary embodiment, the channel layer 706 contacts neither the first source electrode 704 nor first drain electrode 705, and has gaps with the first source electrode 704 and first drain electrode 705. A second source electrode 707 is formed to fill the gap and contact both the first source electrode 704 and channel layer 706. A second drain electrode 708 is formed to fill the gap and contact both the first drain electrode 705 and channel layer 706.

In addition, in the field-effect transistor according to the fifth exemplary embodiment, the first source electrode 704 and first drain electrode 705 extend over steps generated owing to the thickness of the gate insulating film 703, but stop at portions in contact with steps generated under the influence of the thickness of the gate electrode 702. The steps generated under the influence of the thickness of the gate electrode 702 determine the positions of the end portions of the first source electrode 704 and first drain electrode 705 that face each other in self alignment.

The fifth exemplary embodiment can shorten the length by which the gate electrode 702 and first source electrode 704 overlap each other, and the length by which the gate electrode 702 and first drain electrode 705 overlap each other, compared to the above-described fourth exemplary embodiment. Decreasing the widths of the second source electrode 707 and second drain electrode 708 in the longitudinal direction of the channel is limited due to limitations imposed by the pattern formation technique. However, the fifth exemplary embodiment can further decrease the interval between the first source electrode 704 and the first drain electrode 705 without excessively decreasing these widths. Compared to the fourth exemplary embodiment, the fifth exemplary embodiment can reduce the area occupied by a field-effect transistor having the same channel length and channel width, increasing the device density.

Gaps are formed between the first source electrode 704 and first drain electrode 705, and the channel layer 706, similar to the third exemplary embodiment. The gaps have the same effects as those described in the fourth exemplary embodiment.

### Sixth Exemplary Embodiment

The sixth exemplary embodiment of the present invention will be described with reference to FIG. 8. FIG. 8 is a sectional view schematically showing an example of the structure of a field-effect transistor in the sixth exemplary embodiment. In the field-effect transistor according to the sixth exemplary embodiment, a gate electrode 702 is formed on a substrate 701 made of, e.g., an organic resin. A gate insulating film 703 is formed to cover the upper surface and three side surfaces of the gate electrode 702. A first source electrode 704 and first drain electrode 705 are formed so that they extend over steps generated owing to the thickness of the gate insulating film 703, and contact steps generated owing to the thickness of the gate electrode 702.

A channel layer 706 is formed in a region interposed between the first source electrode 704 and the first drain electrode 705 on the gate insulating film 703. Also in the sixth exemplary embodiment, as well as the fourth exemplary embodiment, the channel layer 706 contacts neither the first source electrode 704 nor first drain electrode 705, and has gaps with the first source electrode 704 and first drain electrode 705. A second source electrode 707 is formed to fill the gap and contact both the first source electrode 704 and channel layer 706. A second drain electrode 708 is formed to fill the gap and contact both the first drain electrode 705 and channel layer 706.

Further, in the field-effect transistor according to the sixth exemplary embodiment, the first source electrode 704 and first drain electrode 705 extend over steps generated owing to the thickness of the gate insulating film 703, but stop at portions in contact with steps generated under the influence of the thickness of the gate electrode 702.

The above structure is the same as that in the fifth exemplary embodiment. In the field-effect transistor according to the sixth exemplary embodiment, a passivation layer 809 is formed between the second source electrode 707 and the second drain electrode 708 on the channel layer 706.

A method of manufacturing the field-effect transistor in the sixth exemplary embodiment will be exemplified. A desired ink pattern is formed (drawn) on a 75-μm thick polyimide substrate 701 by, e.g., an inkjet printer using an ink in which silver nanoparticles are dispersed in a medium. The formed pattern is then dried. The pattern is heated to 200° C. to be baked and sintered, forming a gate electrode 702.

A solution of an insulating material containing an organic polymer such as polyimide is applied by a dispenser to cover the upper surface and three side surfaces of the gate electrode 702. The formed pattern (coating film) is fired (thermally cured) at 180° C., forming a gate insulating film 703. The thickness of the gate insulating film 703 is not particularly limited. However, if the gate insulating film 703 is excessively thin, it becomes difficult to effectively suppress the leakage current between the gate electrode and another electrode. If the gate insulating film 703 is excessively thick, the switching phenomenon of an active layer by the gate bias voltage cannot be effectively controlled. Thus, the thickness of the gate insulating film 703 preferably falls within the range of 10 to 1,000 nm.

Next, a first source electrode 704 and first drain electrode 705 are formed. First, a paste is prepared by mixing, with a binder resin, silver nanoparticles whose surface is stabilized by an organic material. Then, the paste is formed into desired patterns each compliant with an electrode shape using, e.g., a screen printing method, and the formed patterns are dried. These patterns serving as the first source electrode 704 and first drain electrode 705 are printed (formed) so that they extend over steps generated owing to the thickness of the gate insulating film 703, and contact steps generated owing to the thickness of the gate electrode 702. The formed patterns are heated to 180° C. to be baked and sintered, forming the first source electrode 704 and first drain electrode 705.

After forming the first source electrode 704 and first drain electrode 705 in this fashion, a CNT ink in which single-walled nanotubes exhibiting semiconductor characteristics are dispersed in dichloroethane is dropped to a predetermined location (channel formation region) and dried, forming a channel layer 706 from the CNT random network. The random network is a p-type semiconductor. The channel layer 706 contacts neither the first source electrode 704 nor first drain electrode 705, and has gaps with the first source electrode 704 and first drain electrode 705.

Thereafter, a passivation layer 809 is formed. For example, a resin with low gas permeability is used. A solution of this resin is applied into a pattern by a screen printing method or the like, forming a resin pattern at the center of the channel layer 706. The resin solution used in pattern formation has high viscosity to a certain degree to suppress the spread of the formed resin pattern on the channel layer 706. After forming the resin pattern, the formed resin pattern is heated to be cured, forming the passivation layer 809.

Next, a second source electrode 707 and second drain electrode 708 are formed from a material mainly containing palladium having a large work function not to form a Schottky barrier or the like between the second source electrode 707 and second drain electrode 708, and the channel layer 706. For example, an ink pattern to contact both the first source electrode 704 and channel layer 706, and an ink pattern to contact both the first drain electrode 705 and channel layer 706 are formed by a well-known inkjet printer using an ink mainly containing palladium. The formed ink patterns are heated to 180° C. to be baked and sintered, forming the second source electrode 707 and second drain electrode 708.

According to the sixth exemplary embodiment, the passivation layer 809 defines the channel length serving as the interval between the second source electrode 707 and the second drain electrode 708. If the passivation layer 809 can be formed at high dimensional accuracy, the manufacturing error of the channel length can be reduced. By forming the passivation layer 809 from a material which hardly transmits gas and the like, as described above, the channel layer 706 covered with the passivation layer 809 can be protected from oxygen, water, and the like in an external environment. The sixth exemplary embodiment can, therefore, reduce aged deterioration of device characteristics and prolong the service life of the device.

### Seventh Exemplary Embodiment

The seventh exemplary embodiment of the present invention will be described with reference to FIG. 9. FIG. 9 is a plan view showing an example of the arrangement of part of a circuit device in the seventh exemplary embodiment. This circuit device is formed using field-effect transistors in the present invention.

The circuit device includes a plurality of word lines 911 to 914, a plurality of plate lines 916 to 919, and a plurality of bit lines 901 to 904 which cross the word lines 911 to 914 at right angles. The ends of the word lines 911 to 914 and plate lines 916 to 919 on one side are connected to a Y-peripheral circuit 922. The ends of the bit lines 901 to 904 on one side are connected to an X-peripheral circuit 921. Each of the X-peripheral circuit 921 and Y-peripheral circuit 922 includes a decoder circuit, driver circuit, and ON/OFF switch.

Basic cells 923 each having the field-effect transistor exemplified in one of the first to sixth exemplary embodiments described above are arranged in a region where the word lines 911 to 914 and plate lines 916 to 919 cross the bit lines 901 to 904. FIG. 9 exemplifies a circuit device in which 4×4 basic cells 923 are arranged (arrayed).

The basic cell 923 has three nodes, and the respective nodes are connected to the bit line, word line, and plate line, respectively. For example, the basic cell 923 surrounded by the broken line in FIG. 9 is connected to the word line 912, bit line 902, and plate line 917.

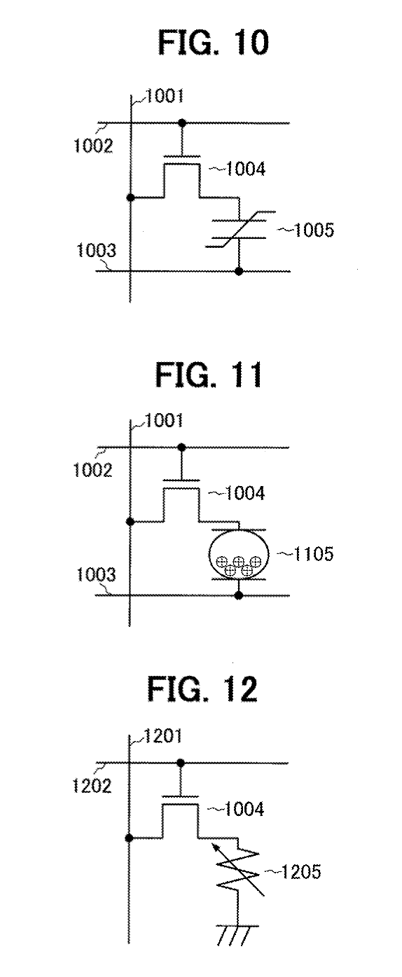

As exemplified in the circuit diagram of FIG. 10 (first example), the basic cell includes a selection transistor 1004, and a ferroelectric capacitor 1005 series-connected to the source (drain) electrode of the selection transistor 1004. The other terminal of the ferroelectric capacitor 1005 is connected to a plate line 1003. The source (drain) electrode (terminal) of the selection transistor 1004 is connected to a bit line 1001, and the gate electrode of the selection transistor 1004 is connected to a word line 1002.

The selection transistor 1004 is, for example, the field-effect transistor in one of the foregoing fourth to sixth exemplary embodiments. The selection transistor 1004 operates to select a predetermined ferroelectric capacitor 1005 in the two-dimensional array. A voltage determined by the potential difference between the bit line 1001 and the plate line 1003 is applied to the selected ferroelectric capacitor 1005, which functions as a ferroelectric RAM.

As described in the fourth to sixth exemplary embodiments, the circuit device in the seventh exemplary embodiment can be fabricated on a plastic substrate by a printing method, so a large-area ferroelectric RAM can be manufactured at low cost. The field-effect transistor according to the present invention can reduce the parasitic resistance on the current path, decreasing a voltage drop generated across the selection transistor 1004. The operating margin of the ferroelectric RAM becomes wide, and the operation stability improves.

Another example (second example) of the basic cell will be described with reference to FIG. 11. FIG. 11 is a circuit diagram showing another example of the structure of the basic cell. This basic cell includes the selection transistor 1004, and an electrophoretic microcapsule 1105, called an electronic ink, which is series-connected to the source (drain) electrode of the selection transistor 1004. The other terminal of the ferroelectric capacitor 1005 is connected to the plate line 1003. The other terminal of the selection transistor 1004 is connected to the bit line 1001, and the gate electrode of the selection transistor 1004 is connected to the word line 1002.

The selection transistor 1004 suffices to be the field-effect transistor in one of the fourth to sixth exemplary embodiments described above. The selection transistor 1004 operates to select a predetermined electrophoretic microcapsule 1105 in the two-dimensional array. A voltage determined by the potential difference between the bit line 1001 and the plate line 1003 is applied to the selected electrophoretic microcapsule 1105, changing the display state of the electrophoretic microcapsule 1105. As described in the fourth to sixth exemplary embodiments, this circuit device can be fabricated on a plastic substrate by a printing method, and a large-area, flexible display device can be manufactured at low cost. The field-effect transistor according to the present invention can reduce the parasitic resistance on the current path, decreasing a voltage drop generated across the selection transistor 1004. The operating margin of the display device becomes wide, and power consumption in display switching can be reduced.

Still another example (third example) of the basic cell will be described with reference to FIG. 12. FIG. 12 is a circuit diagram showing still another example of the structure of the basic cell. This basic cell includes the selection transistor 1004, and a variable resistor 1205 series-connected to the source (drain) electrode of the selection transistor 1004. The other terminal of the variable resistor 1205 is grounded. The other terminal of the selection transistor 1004 is connected to a bit line 1201, and the gate electrode of the selection transistor 1004 is connected to a word line 1202.

The selection transistor 1004 suffices to be the thin-film transistor in one of the fourth to sixth exemplary embodiments of the present invention. The selection transistor 1004 operates to select a predetermined variable resistor 1205 in the two-dimensional array. A predetermined current or predetermined voltage is applied from the X-peripheral circuit 921 (FIG. 9) to the selected variable resistor 1205 via the bit line 1201 (one of the bit lines 901 to 904) and the selection transistor 1004, detecting the resistance value of the variable resistor 1205.

As the variable resistor 1205, a resistor whose resistance value changes depending on the magnetic field or pressure is usable. That is, this circuit device (third example) is a sensor array capable of detecting the two-dimensional distribution of the magnetic field or pressure. The circuit device in the above-described exemplary embodiment can be fabricated on a plastic substrate by a printing method, and a large-area, flexible sensor array can be manufactured at low cost. The seventh exemplary embodiment can decrease the resistance generated by the selection transistor 1004 on the current path, enabling high-precision sensing.

As described above, the field-effect transistor in the present invention has a feature in that electrodes are formed in two regions. In the first region (first and second electrodes), the step of the device portion is covered. The material used in this region suffices to be a conductor, and a relatively low-cost material is available. Such a low-cost material hardly raises the manufacturing cost even when a sufficient amount of liquid material is used to cover the step. In the second electrode region (third and fourth electrodes), the first region and channel layer electrically contact each other. The material used in this region is determined in accordance with the semiconductor material in contact with it.

As described above, to decrease the Schottky barrier at the interface between the electrode and the semiconductor, gold, platinum, iridium, palladium, cobalt, nickel, and the like having large work functions are suitable for a p-type semiconductor. To make a contact with an n-type semiconductor, silver, aluminum, titanium, tantalum, niobium, zinc, tin, indium, gallium, manganese, and the like having small work functions are suited. Since the second electrode region is flat, satisfactory reliability can be ensured by a small amount of liquid material.

The regions of the third and fourth electrodes determine the contact resistance with the channel layer, and define the channel length and channel width of the field-effect transistor (TFT). That is, these regions are important elements which determine device characteristics and variations of characteristics. Generally in printing, the resolution and accuracy of a printed pattern become higher for a smaller amount of discharged ink (liquid material). Hence, the present invention can provide a high-performance field-effect transistor excellent in uniformity and reliability at low cost. The field-effect transistor in the present invention can be formed on a lightweight resin substrate by a printing method, and thus can be easily applied to a large-area semiconductor device. A large-scale display device, sensor array, and the like can be manufactured at low cost.

The exemplary embodiments of the present invention have been described, but the foregoing examples can be variously changed and modified based on the technical idea of the invention. For example, the channel layer is not limited to carbon nanotubes, and may be formed from a carbon nanomaterial containing a graphene ribbon. By using the carbon nanomaterial, a field-effect transistor equivalent to one using carbon nanotubes can be obtained. The channel layer is not limited to zinc oxide nanowires, and may be formed from another oxide semiconductor having nanostructures. The channel layer can be similarly formed from a semiconductor having nanostructures such as silicon nanowires. When such nanostructures are used, a channel layer can be formed in the foregoing way by a pattern formation technique using an ink (paste) in which the nanostructures are dispersed. The channel layer can also be formed from a semiconductive polymer.

In the above-described exemplary embodiments, the first source electrode and first drain electrode contain silver because they are formed using an ink of silver fine particles. However, the first source electrode and first drain electrode are not limited to silver, and may be formed similarly using copper. Alternatively, the first source, electrode and first drain electrode may be formed using a carbon material such as carbon nanotubes similarly to silver.

### INDUSTRIAL APPLICABILITY

As described above, according to the present invention, a field-effect transistor used for a large-screen flat display can be manufactured on a lightweight resin substrate or the like by a printing method. The present invention implements an effective structure especially when a plurality of nanostructures such as carbon nanotubes or zinc oxide nanowires are used as the channel layer. The present invention can provide a field-effect transistor which reduces the contact resistance at the interface between the channel layer and the electrode and is excellent in electrical characteristics. The field-effect transistor according to the present invention allows the use of a manufacturing method such as a printing method advantageous in reducing the cost and increasing the area, and is excellent in uniformity and stability. By using the field-effect transistor of the present invention, a circuit device such as a large-scale display device or sensor array can be provided at low cost.

The present invention has been described above with reference to the exemplary embodiments. However, the present invention is not limited to the above exemplary embodiments. It will readily occur to those skilled in the art that the arrangement and details of the present invention can be variously changed and modified without departing from the scope of the invention.

This application is based upon and claims the benefit of priority from Japanese Patent Application No. 2008-192642, filed on Jul. 25, 2008, the disclosure of which is incorporated herein in its entirety by reference.

1. A field-effect transistor comprising at least:
a gate electrode which is formed on a substrate;
a gate insulating film which is formed to cover a channel formation region of an upper surface of said gate electrode, and cover part of a first side portion and part of a second side portion of said gate electrode that face each other;
a first electrode and a second electrode which are formed on side of the first side portion and on side of the second side portion, respectively, said first electrode and said second electrode having end portions facing each other on said gate insulating film via the channel formation region;
a channel layer which is formed in the channel formation region on said gate insulating film;
a third electrode which is formed in contact with said channel layer on the side of the first side portion, and connects said first electrode and said channel layer; and
a fourth electrode which is formed in contact with said channel layer on the side of the second side portion, and connects said second electrode and said channel layer,
wherein highest portions of the facing end portions of said first electrode and said second electrode are formed higher than an upper surface of said gate insulating film in the channel formation region.

2. A field-effect transistor according to claim 1, wherein
gaps are formed between said first electrode and said channel layer and between said second electrode and said channel layer, and
said third electrode and said fourth electrode are formed to fill the gaps.

3. A field-effect transistor according to claim 1, further comprising a passivation layer which is formed on said channel layer between said third electrode and said fourth electrode.

4. A field-effect transistor according to claim 1, wherein said channel layer is formed from a carbon nanomaterial containing a carbon nanotube and a graphene ribbon.

5. A field-effect transistor according to claim 1, wherein said channel layer is formed from an oxide semiconductor having a nanostructure containing a zinc oxide nanowire.

6. A field-effect transistor according to claim 1, wherein said channel layer is formed from a semiconductor having a nanostructure containing a silicon nanowire.

7. A field-effect transistor according to claim 1, wherein said channel layer is formed from a semiconductive polymer.

8. A field-effect transistor according to claim 1, wherein said third electrode and said fourth electrode are formed from a mixture of a carbon material having an SP² hybridized orbit and a metal.

9. A field-effect transistor according to claim 1, wherein said third electrode and said fourth electrode essentially consist of at least one material selected from the group consisting of gold, platinum, iridium, palladium, cobalt, and nickel.

10. A field-effect transistor according to claim 1, wherein said third electrode and said fourth electrode essentially consist of at least one material selected from the group consisting of silver, aluminum, titanium, tantalum, niobium, zinc, tin, indium, gallium, and manganese.

11. A field-effect transistor according to claim 1, wherein said third electrode and said fourth electrode are formed from an organic conductive material.

12. A field-effect transistor according to claim 1, wherein said first electrode and said second electrode essentially consist of at least one material selected from the group consisting of silver and copper.

13. A field-effect transistor according to claim 1, wherein said first electrode and said second electrode are formed from a carbon material containing a carbon nanotube.

14. A field-effect transistor according to claim 1, wherein said channel layer is formed through one of a coating step and a printing step, and a drying step.

15. A field-effect transistor according to claim 1, wherein said third electrode and said fourth electrode are formed through one of a coating step and a printing step, a drying step, and a sintering step.

16. A field-effect transistor according to claim 1, wherein the substrate is formed from one of a resin and a multilayered resin film.

17. A circuit device formed by arranging a plurality of field-effect transistors defined in claim 1 on a substrate.

18. A field-effect transistor comprising at least:
a gate electrode which is formed on a substrate;
a gate insulating film which is formed to cover an upper surface and at least two side surfaces of said gate electrode;
a first electrode and a second electrode which are formed to extend over steps on said gate insulating film that are generated owing to thicknesses of said gate electrode and said gate insulating film;
a channel layer which is formed in a region interposed between said first electrode and said second electrode on said gate insulating film;
a third electrode which is formed in contact with both said first electrode and said channel layer; and
a fourth electrode which is formed in contact with both said second electrode and said channel layer.

19. A field-effect transistor according to claim 18, wherein
gaps are formed between said first electrode and said channel layer and between said second electrode and said channel layer, and
said third electrode and said fourth electrode are formed to fill the gaps.

20. A field-effect transistor according to claim 18, further comprising a passivation layer which is formed on said channel layer between said third electrode, and said fourth electrode.

21. A field-effect transistor according to claim 18, wherein said channel layer is formed from a carbon nanomaterial containing a carbon nanotube and a graphene ribbon.

22. A field-effect transistor according to claim 18, wherein said channel layer is formed from an oxide semiconductor having a nanostructure containing a zinc oxide nanowire.

23. A field-effect transistor according to claim 18, wherein said channel layer is formed from a semiconductor having a nanostructure containing a silicon nanowire.

24. A field-effect transistor according to claim 18, wherein said channel layer is formed from a semiconductive polymer.

25. A field-effect transistor according to claim 18, wherein said third electrode and said fourth electrode are formed from a mixture of a carbon material having an SP² hybridized orbit and a metal.

26. A field-effect transistor according to claim 18, wherein said third electrode and said fourth electrode essentially consist of at least one material selected from the group consisting of gold, platinum, iridium, palladium, cobalt, and nickel.

27. A field-effect transistor according to claim 18, wherein said third electrode and said fourth electrode essentially consist of at least one material selected from the group consisting of silver, aluminum, titanium, tantalum, niobium, zinc, tin, indium, gallium, and manganese.

28. A field-effect transistor according to claim 18, wherein said third electrode and said fourth electrode are formed from an organic conductive material.

29. A field-effect transistor according to claim 18, wherein said first electrode and said second electrode essentially consist of at least one material selected from the group consisting of silver and copper.

30. A field-effect transistor according to claim 18, wherein said first electrode and said second electrode are formed from a carbon material containing a carbon nanotube.

31. A field-effect transistor according to claim 18, wherein said channel layer is formed through one of a coating step and a printing step, and a drying step.

32. A field-effect transistor according to claim 18, wherein said third electrode and said fourth electrode are formed through one of a coating step and a printing step, a drying step, and a sintering step.

33. A field-effect transistor according to claim 18, wherein the substrate is formed from one of a resin and a multilayered resin film.

34. A circuit device formed by arranging a plurality of field-effect transistors defined in claim 18 on a substrate.

35. A field-effect transistor comprising at least:
a gate electrode which is formed on a substrate;
a gate insulating film which is formed to cover an upper surface and at least two side surfaces of said gate electrode;
a first electrode and a second electrode which are formed to extend over steps generated owing to a thickness of said gate insulating film, and contact steps of said gate insulating film that are generated by reflecting a thickness of said gate electrode;
a channel layer which is formed in a flat region on said gate insulating film between said first electrode and said second electrode;
gaps which are formed between said first electrode and said second electrode, and said channel layer;
a third electrode which is formed in contact with both said first electrode and said channel layer; and
a fourth electrode which is formed in contact with both said second electrode and said channel layer.

36. A field-effect transistor according to claim 35, further comprising a passivation layer which is formed on said channel layer between said third electrode and said fourth electrode.

37. A field-effect transistor according to claim 35, wherein said channel layer is formed from a carbon nanomaterial containing a carbon nanotube and a graphene ribbon.

38. A field-effect transistor according to claim 35, wherein said channel layer is formed from an oxide semiconductor having a nanostructure containing a zinc oxide nanowire.

39. A field-effect transistor according to claim 35, wherein said channel layer is formed from a semiconductor having a nanostructure containing a silicon nanowire.

40. A field-effect transistor according to claim 35, wherein said channel layer is formed from a semiconductive polymer.

41. A field-effect transistor according to claim 35, wherein said third electrode and said fourth electrode are formed from a mixture of a carbon material having an SP² hybridized orbit and a metal.

42. A field-effect transistor according to claim 35, wherein said third electrode and said fourth electrode essentially consist of at least one material selected from the group consisting of gold, platinum, iridium, palladium, cobalt, and nickel.

43. A field-effect transistor according to claim 35, wherein said third electrode and said fourth electrode essentially consist of at least one material selected from the group consisting of silver, aluminum, titanium, tantalum, niobium, zinc, tin, indium, gallium, and manganese.

44. A field-effect transistor according to claim 35, wherein said third electrode and said fourth electrode are formed from an organic conductive material.

45. A field-effect transistor according to claim 35, wherein said first electrode and said second electrode essentially consist of at least one material selected from the group consisting of silver and copper.

46. A field-effect transistor according to claim 35, wherein said first electrode and said second electrode are formed from a carbon material containing a carbon nanotube.

47. A field-effect transistor according to claim 35, wherein said channel layer is formed through one of a coating step and a printing step, and a drying step.

48. A field-effect transistor according to claim 35, wherein said third electrode and said fourth electrode are formed through one of a coating step and a printing step, a drying step, and a sintering step.

49. A field-effect transistor according to claim 35, wherein the substrate is formed from one of a resin and a multilayered resin film.

50. A circuit device formed by arranging a plurality of field-effect transistors defined in claim 35 on a substrate.
